(19) United States
(12) Patent Application Publication
(10) Pub. No.: US 2026/0142621 A1
(43) Pub. Date: May 21, 2026

(54) LOW NOISE AMPLIFIER OPERATING IN X-BAND AND KU-BAND

(71) Applicant: WAVEPIA CO., LTD., Gyeonggi-do (KR)

(72) Inventors: Sang-Hun LEE, Gyeonggi-do (KR); Sang-Yeol LEE, Gyeonggi-do (KR)

(21) Appl. No.: 19/319,969

(22) Filed: Sep. 5, 2025

(30) Foreign Application Priority Data
Nov. 21, 2024 (KR) 10-2024-0167468

(51) Int. Cl. H03F 1/08; H03F 1/34; H03F 3/45

(52) U.S. Cl. CPC H03F 1/086; H03F 1/342; H03F 3/4521; H03F 2200/168; H03F 2200/294; H03F 2200/372; H03F 2200/451

(57) ABSTRACT

A low noise amplifier operating in an X-band and a Ku-band, the amplifier includes: a differential input unit that adjusts an impedance of an input low noise signal; a differential amplification unit comprising a positive wideband filter that feeds back an 8 to 16 GHz band signal from a positive low noise signal transmitted by the differential input unit, a negative wideband filter that feeds back an 8 to 16 GHz band signal from a negative low noise signal transmitted by the differential input unit, a positive amplification unit, and a negative amplification unit that amplifies a negative low noise signal transmitted by the differential input unit; and a differential output unit that outputs a positive low noise signal amplified by the positive amplification unit and a negative low noise signal amplified by the negative amplification unit.

### BACKGROUND

The present disclosure relates to a low noise amplifier operating in an X-band and a Ku-band, and more particularly, to a low noise amplifier operating in an X-band and a Ku-band, which can stably operate in an 8 to 16 GHz band by separating an input low noise signal into a positive low noise signal and a negative low noise signal, and differentially amplifying the separated positive low noise signal and negative low noise signal by feeding back the 8 to 16 GHz band signal through a wideband filter.

In general, beamforming techniques have been widely used in various applications such as radar systems, mobile electronic devices, and satellite communications due to their superior capabilities to automatically control signal directivity compared to conventional mechanical approaches.

Recently, the powerful integration capabilities of silicon process technologies have helped to significantly reduce production costs compared to the use of individual components while maintaining the same or better quality, which leads to a lot of research focused on beamforming techniques in X-band and Q-band applications.

However, low noise amplifiers are essential for X-band and Ku-band beamforming circuits to perform a stable operation, but conventional low noise amplifiers have difficulty in designing to have immunity to noise in an 8 to 16 GHz band.

Patent Document 1: Korean Patent Publication No. 10-2022-0002907 (published on January 7, 2022)

### SUMMARY OF THE INVENTION

A problem to be solved by the present disclosure is to provide a low noise amplifier operating in an X-band and a Ku-band, which can stably operate in an 8 to 16 GHz band by separating an input low noise signal into a positive low noise signal and a negative low noise signal, and differentially amplifying the separated positive low noise signal and negative low noise signal by feeding back the 8 to 16 GHz band signal through a wideband filter.

Technical problems to be solved in the present disclosure may not be limited to the above-described problems and other problems, which are not mentioned herein, will definitely be understood by those skilled in the art from the following description.

In order to achieve the foregoing objectives, a low noise amplifier operating in an X-band and a Ku-band, the amplifier including a differential input unit 100 that adjusts an impedance of an input low noise signal, and separates the low noise signal into a positive signal and a negative signal to transmit the separated signals, a differential amplification unit 200 including a positive wideband filter 221 that feeds back an 8 to 16 GHz band signal from a positive low noise signal transmitted by the differential input unit 100, a negative wideband filter 222 that feeds back an 8 to 16 GHz band signal from a negative low noise signal transmitted by the differential input unit 100, a positive amplification unit 211 that amplifies a positive low noise signal transmitted by the differential input unit 100, and a negative amplification unit 212 that amplifies a negative low noise signal transmitted by the differential input unit 100, and a differential output unit 300 that outputs a positive low noise signal amplified by the positive amplification unit 211 and a negative low noise signal amplified by the negative amplification unit 212.

Preferably, the positive wideband filter 221 or the negative wideband filter 222 may include a resistor and a capacitor.

Preferably, the positive amplification unit 211 may be configured by connecting a first MOS transistor and a third MOS transistor in series, the positive low noise signal is transmitted to a gate of the first MOS transistor, a power supply voltage may be applied to a gate of the third MOS transistor to turn it on, and a first bypass capacitor may be disposed between the gate of the third MOS transistor and the ground.

Preferably, the negative amplification unit 212 may be configured by connecting a second MOS transistor and a fourth MOS transistor in series, the negative low noise signal may be transmitted to a gate of the second MOS transistor, the power supply voltage may be applied to a gate of the fourth MOS transistor to turn it on, and a second bypass capacitor may be disposed between the gate of the fourth MOS transistor and the ground.

Preferably, a first degeneration inductor that stabilizes an impedance of the first MOS transistor may be disposed between a source of the first MOS transistor and the ground.

Preferably, a second degeneration inductor that stabilizes an impedance of the second MOS transistor may be disposed between a source of the second MOS transistor and the ground.

Preferably, the differential input unit 100 may include a transformer, a capacitor, and a resistor.

Preferably, the differential output unit 300 may remove a DC component by passing the amplified positive low noise signal through a first blocking capacitor and remove a DC component by passing the amplified negative low noise signal through a second blocking capacitor.

A low noise amplifier operating in an X-band and a Ku-band according to embodiments of the present disclosure may stably operate in an 8 to 16 GHz band by separating an input low noise signal into a positive low noise signal and a negative low noise signal, and differentially amplifying the separated positive low noise signal and negative low noise signal by feeding back the 8 to 16 GHz band signal through a wideband filter.

### BRIEF DESCRIPTION OF THE DRAWINGS

FIG. 1 is a circuit diagram of a low noise amplifier operating in an X-band and a Ku-band according to one embodiment of the present disclosure.

### DETAILED DESCRIPTION OF THE PREFERRED EMBODIMENT

The detailed description of the present disclosure described below refers to the accompanying drawings, which show, by way of illustration, specific embodiments to carry out the present disclosure. These embodiments are described in sufficient detail to enable those skilled in the art to carry out the present disclosure. It should be understood that various embodiments of the present disclosure are different from one another but are not necessarily mutually exclusive.

For example, specific shapes, structures and characteristics described herein may be implemented in other embodiments without departing from the concept and scope of the present disclosure in connection with one embodiment. In addition, it should be understood that the locations or arrangement of individual elements within each disclosed embodiment may be changed without departing from the concept and scope of the present disclosure.

Therefore, the following detailed description is not to be taken in a limiting sense, and the scope of the present disclosure is defined only by the appended claims along with the entire scope of equivalents thereof, if properly described.

Hereinafter, with reference to the accompanying drawings, a low noise amplifier operating in an X-band and a Ku-band according to embodiments of the present disclosure will be described.

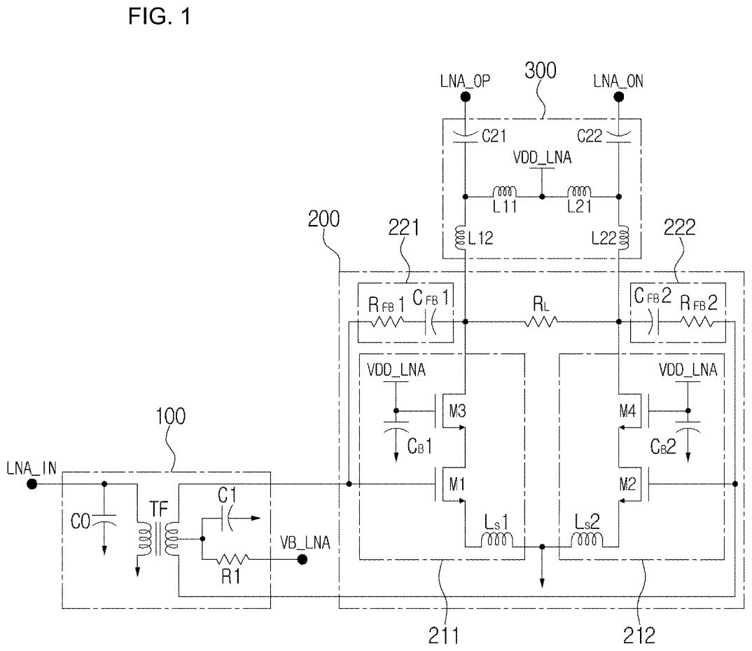

A low noise amplifier operating in an X-band and a Ku-band according to an embodiment of the present disclosure may, as shown in FIG. 1, include a differential input unit 100 that adjusts an impedance of an input low noise signal LNA_IN, and separates the low noise signal into a positive signal and a negative signal to transmit the separated signals, a differential amplification unit 200 including a positive wideband filter 221 that feeds back an 8 to 16 GHz band signal from a positive low noise signal transmitted by the differential input unit 100, a negative wideband filter 222 that feeds back an 8 to 16 GHz band signal from a negative low noise signal transmitted by the differential input unit 100, a positive amplification unit 211 that amplifies a positive low noise signal transmitted by the differential input unit 100, and a negative amplification unit 212 that amplifies a negative low noise signal transmitted by the differential input unit 100, and a differential output unit 300 that outputs a positive low noise signal amplified by the positive amplification unit 211 and a negative low noise signal amplified by the negative amplification unit 212 LNA_OP, LNA-ON.

Here, the positive wideband filter 221 may include a resistor RFB1 and a capacitor CFB1, and the negative wideband filter 222 may include a resistor RFB2 and a capacitor CFB2.

In addition, the positive amplification unit 211 may be configured by connecting a first MOS transistor M1 and a third MOS transistor M3 in series, the positive low noise signal may be transmitted to a gate of the first MOS transistor M1, a power supply voltage VDD_LNA may be applied to a gate of the third MOS transistor M3 to turn it on, and a first bypass capacitor CB1 may be disposed between the gate of the third MOS transistor M3 and the ground.

Meanwhile, the negative amplification unit 212 may be configured by connecting a second MOS transistor M2 and a fourth MOS transistor M4 in series, the negative low noise signal may be transmitted to a gate of the second MOS transistor M2, the power supply voltage VDD_LNA may be applied to a gate of the fourth MOS transistor M4 to turn it on, and a second bypass capacitor CB2 may be disposed between the gate of the fourth MOS transistor M4 and the ground.

Here, a first degeneration inductor LS1 that stabilizes an impedance of the first MOS transistor M1 may be disposed between a source of the first MOS transistor M1 and the ground.

In addition, a second degeneration inductor LS2 that stabilizes an impedance of the second MOS transistor M2 may be disposed between a source of the second MOS transistor M2 and the ground.

Meanwhile, the differential input unit 100 may include a transformer TF, capacitors C0, C1 and a resistor R1 to adjust an impedance of the input low noise signal LNA_IN and separate the low noise signal into a positive signal and a negative signal to transmit the separated signals.

In addition, the differential output unit 300 removes the DC component by passing the amplified positive low noise signal through the first blocking capacitor C21, and removes the DC component by passing the amplified negative low noise signal through the second blocking capacitor C22.

Here, the power supply voltage VDD_LNA may be transmitted to a drain of the third MOS transistor M3 through inductors L11, L12, and the power supply voltage VDD_LNA may be transmitted to a drain of the fourth MOS transistor M4 through inductors L21, L22.

In the above, although the present disclosure has been described and shown with reference to preferred embodiments for illustrating the principles of the present disclosure, the present disclosure is not limited to the exact construction and operation shown and described.

Rather, those skilled in the art will readily appreciate that many changes and modifications to the present disclosure can be made without departing from the concept and scope of the appended claims.

Accordingly, all such appropriate changes, modifications, and equivalents should also be considered to fall within the scope of the present disclosure.

What is claimed is:

1. A low noise amplifier operating in an X-band and a Ku-band, the amplifier comprising:
a differential input unit that adjusts an impedance of an input low noise signal, and separates the low noise signal into a positive signal and a negative signal to transmit the separated signals;
a differential amplification unit comprising a positive wideband filter that feeds back an 8 to 16 GHz band signal from a positive low noise signal transmitted by the differential input unit, a negative wideband filter that feeds back an 8 to 16 GHz band signal from a negative low noise signal transmitted by the differential input unit, a positive amplification unit that amplifies a positive low noise signal transmitted by the differential input unit, and a negative amplification unit that amplifies a negative low noise signal transmitted by the differential input unit; and
a differential output unit that outputs a positive low noise signal amplified by the positive amplification unit and a negative low noise signal amplified by the negative amplification unit.

2. The low noise amplifier of claim 1, wherein the positive wideband filter or the negative wideband filter comprises a resistor and a capacitor.

3. The low noise amplifier of claim 2, wherein the positive amplification unit is configured by connecting a first MOS transistor and a third MOS transistor in series, the positive low noise signal is transmitted to a gate of the first MOS transistor, a power supply voltage is applied to a gate of the third MOS transistor to turn it on, and a first bypass capacitor is disposed between the gate of the third MOS transistor and the ground.

4. The low noise amplifier of claim 3, wherein the negative amplification unit is configured by connecting a second MOS transistor and a fourth MOS transistor in series, the negative low noise signal is transmitted to a gate of the second MOS transistor, the power supply voltage is applied to a gate of the fourth MOS transistor to turn it on, and a second bypass capacitor is disposed between the gate of the fourth MOS transistor and the ground.

5. The low noise amplifier of claim 4, wherein a first degeneration inductor that stabilizes an impedance of the first MOS transistor is disposed between a source of the first MOS transistor and the ground.

6. The low noise amplifier of claim 4, wherein a second degeneration inductor that stabilizes an impedance of the second MOS transistor is disposed between a source of the second MOS transistor and the ground.

7. The low noise amplifier of claim 4, wherein the differential input unit comprises a transformer, a capacitor, and a resistor.

8. The low noise amplifier of claim 4, wherein the differential output unit removes a DC component by passing the amplified positive low noise signal through a first blocking capacitor and removes a DC component by passing the amplified negative low noise signal through a second blocking capacitor.
